(19) United States
(12) Patent Application Publication
(10) Pub. No.: US 2002/0169603 A1
(43) Pub. Date: Nov. 14, 2002

(54) ADC resolution enhancement through subband coding

(75) Inventor: Terry L. Sculley, Austin, TX (US)

Correspondence Address: W. Daniel Swayze, Jr., Texas Instruments Incorporated, P.O. Box 655474, MS 3999, Dallas, TX, 75265, US

(73) Assignee: TEXAS INSTRUMENTS INCORPORATED

(21) Appl. No.: 09/849,761

(22) Filed: May 4, 2001

(51) Int. Cl. G10L 21/00; H03M 1/12

(52) U.S. Cl. 704/229; 341/50

(57) ABSTRACT

A method and apparatus for reducing noise in an output signal for particular application with an output signal of an analog-to-digital converter (“ADC”). An ADC is disclosed which includes processing circuitry to divide a signal into a plurality of frequency subbands and then evaluate the signal level in each of those frequency subbands. If the signal level in a particular frequency subband is below a predetermined noise threshold for a predetermined time interval, that frequency subband is muted until the signal level is outside of the threshold level. By “muting” the frequency subband in this way, a portion of the otherwise existing noise may be removed from the output signal.

### BACKGROUND OF THE INVENTION

1. Field of the Invention

The present invention relates generally to analog-to-digital converter (“ADC”) technologies. More particularly, the present invention relates to methods and apparatus for improving the resolution of the output signal from an ADC through subband coding and filtering of the signal to remove noise.

2. State of the Art

Modem semiconductor technologies require ever smaller feature sizes and circuits. While smaller and faster integrated circuit technologies have enabled the development of increased performance digital processing capability, the lower voltage requirements of these technologies have also made the design of high-resolution, low noise analog circuits more difficult. Effective conversion circuitry between analog and digital systems, therefore, is becoming more important as semiconductor technologies shrink.

Analog-to-digital converters (“ADC”s) are widely used in electronic devices to convert analog signals into digital signals. A common structure for a high resolution ADC includes a front-end modulator, such as a delta-sigma modulator, and a decimation filter. Delta-sigma modulators utilize oversampling techniques (i.e., sampling at rates much higher than twice that of the signal bandwidth) to achieve high signal-to-noise ratios through manipulation of the noise spectrum of the analog input signal. Through a delta-sigma modulator, a major component of the quantization noise power of the input signal is shifted to a frequency range higher than the upper frequency limit of the desired signal band. The decimation filter, which typically follows a delta-sigma modulator, is used to remove the energy in frequency regions outside of the intended signal bandwidth, and then reduce the sample rate of the output signal to a level closer to twice the intended signal bandwidth. For example, a delta-sigma modulator intended for audio applications, where the signal bandwidth is approximately 20 Hz to 20 kHz, may produce a digital output at 6.144 MHZ sample rate. Digital filters then remove the energy outside of the 20 Hz-20 kHz signal band and reduce the sample rate to, for example, 48 kHz or 44.1 kHz. Using this form of ADC, however, still results in internally generated noise appearing within the signal bandwidth even if the input signal is precisely zero (noiseless). This approach also reduces the ability to distinguish small signals which may be masked by the noise present across the entire signal bandwidth.

Analog radio receiver technology used a technique called a “squelch operation” which turned off the analog output signal if it was below a given threshold to reduce unnecessary noise (such as at the end of a song or a break in speaking). When the analog output was again above the threshold, the output was again turned on. Because it was generally difficult to sense very low analog noise signals, the squelching technique for purely analog equipment was done only for low quality systems with relatively larger quantities of noise.

In recent times, audio electronics has moved heavily into the digital realm, with digital-to-analog converters (DAC's) needed for conversion of digital data back into the analog realm for playing through speakers or headphones. Now an operation similar to this old radio squelch technique is still employed to reduce noise during quiet periods in the music or digital input material. This is used because it is possible to easily design a mute circuit that gives very low analog noise output, usually much lower noise than a DAC can provide when given a perfect zero-level digital input.

An example of a recent prior art approach for reducing output noise in digital-to-analog converters (“DAC”s) is shown and described with reference to FIGS. 1 and 2. The output signal 8 of the DAC 2 is passed through a mute/unmute circuit 4 before becoming the final output signal 14. To produce the final output signal 14, the mute/unmute circuit 4 either passes the DAC output signal 8 unaffected (unmute), or passes a “zero” level (mute) in response to a mute/umnute control signal 10. The mute/unmute control signal 10 is generated by monitor/control algorithm circuitry 6 which evaluates whether the DAC input signal is zero for a predetermined time τ. When the DAC input signal has been all zeroes for time τ, the mute/unmute control signal 10 goes high to mute the DAC output signal 8 at the mute/unmute circuit 4. Any time the DAC input is not zero, the monitor/control algorithm circuitry 6 sends a mute/unmute control signal 10 which immediately unmutes the DAC output signal 8 at the mute/unmute circuit block 4. Thus, portions of the DAC input signal which are all zeroes for a time longer than τ, but have noise added by the DAC process, are appropriately zeroed out or muted and are not seen in the final output signal 14.

This DAC squelching example is used in CD players, where an audio DAC converts the digitally recorded music to analog, which then drives amplifiers and eventually speakers. When a CD player is between tracks or is changing disks, the system may just provide a perfect digital zero-level to the DAC, but even lower noise output is obtained by muting the DAC output during these times.

Another similar use of this squelching operation is found in the MPEG (Moving Picture Experts Group) compression standards for audio data compression. Here, higher ratio data compression may be accomplished by filtering audio signal data to reduce the number of bits required to store an approximation to the audio signal. In one portion of an MPEG compression approach, a digital audio signal is divided into multiple subbands by a digital filter bank which has a threshold mask pattern specifically chosen for the type of data to be stored. That threshold mask includes an allowable noise threshold for each of a plurality of frequency subbands, and serves as a comparison for the final output signal to determine if the noise threshold is low enough for each frequency subband. Each frequency subband is initially processed using a scaling factor of 1.0. The processed signal is then evaluated for quantization noise. If the quantization noise in any given subband is found to be outside of the mask's noise threshold, the scalefactor for this band is adjusted to reduce the quantization noise and the signal is reprocessed.

Achieving a smaller quantization noise requires a larger number of quantization steps, and, thus, a higher bit rate and less compression. Therefore, in bands where the quantization noise is outside of the band-specific threshold mask value, the signal is preserved with many bits of resolution. In bands where the quantization noise is not outside of the threshold mask value, the signal is preserved with fewer bits of resolution. This information in subband form is then stored in its compressed form for later access. An approximate replica of the original signal may be reconstructed from the compressed data by combining the subband signals into a single output.

### SUMMARY OF THE INVENTION

It is an object of the invention to reduce the noise energy of the output of an ADC without significant loss of output signal quality.

It is another object of the invention to improve the signal to noise ratio of an ADC.

It is yet another object of the invention to increase the effective resolution of an ADC through the use of subband coding.

It is still yet another object of the invention to optimize the signal to noise ratio of an ADC versus an applied input signal.

Generally, the invention involves circuitry and a method for reducing noise in an output signal by dividing the signal band of an output signal into multiple subbands using a filter bank, performing a squelch operation on each subband signal independently, and then combining the subband signals together to form a final output signal.

According to an embodiment of the present invention, a digital filter bank is disclosed to accept a wideband digital input from an ADC and divide it into a plurality of frequency subband signals. A plurality of mute/unmute circuits are also disclosed, each of which accepts one of the plurality of frequency subband signals and compares it to a noise threshold range. If the frequency subband signal is within the threshold range, in response to the comparison, each mute/unmute circuit determines whether to pass the frequency subband signal, or to output an attenuated or reduced signal value. The mute/unmute circuit includes a timing circuit which generates a “mute” control signal only after the frequency subband signal has been within the noise threshold range for a predetermined time. The mute/unmute circuit also generates an “unmute” control signal immediately when the frequency subband signal is outside of the noise threshold range to cause the mute/unmute circuit to pass the present frequency subband signal. The plurality of muted or unmuted frequency subband signals are then recombined into a single digital output.

### BRIEF DESCRIPTION OF THE DRAWINGS

The nature of the present invention as well as other embodiments of the present invention may be more clearly understood by reference to the following detailed description of the invention, to the appended claims, and to the accompanying drawings, wherein:

FIG. 1 is a block diagram of a prior art digital-to-analog converter (“DAC”) circuit which includes post DAC signal processing;

FIG. 2 is a timing diagram for the DAC circuit of FIG. 1;

FIG. 3 is a block diagram of an analog-to-digital converter (“ADC”) which includes post ADC signal processing according to an embodiment of the present invention;

FIG. 4 is a diagram illustrating the processing circuit block of FIG. 3 according to an embodiment of the present invention; and

FIG. 5 is a diagram illustrating a mute/un mute processing circuit according to a particular embodiment of the present invention.

FIG. 6 is a timing diagram for the circuit shown in FIG. 5.

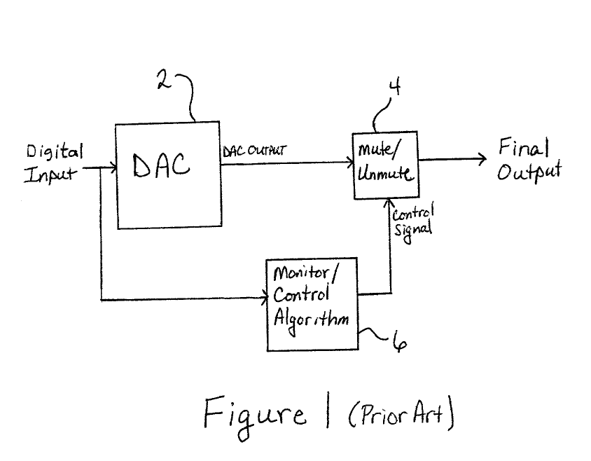

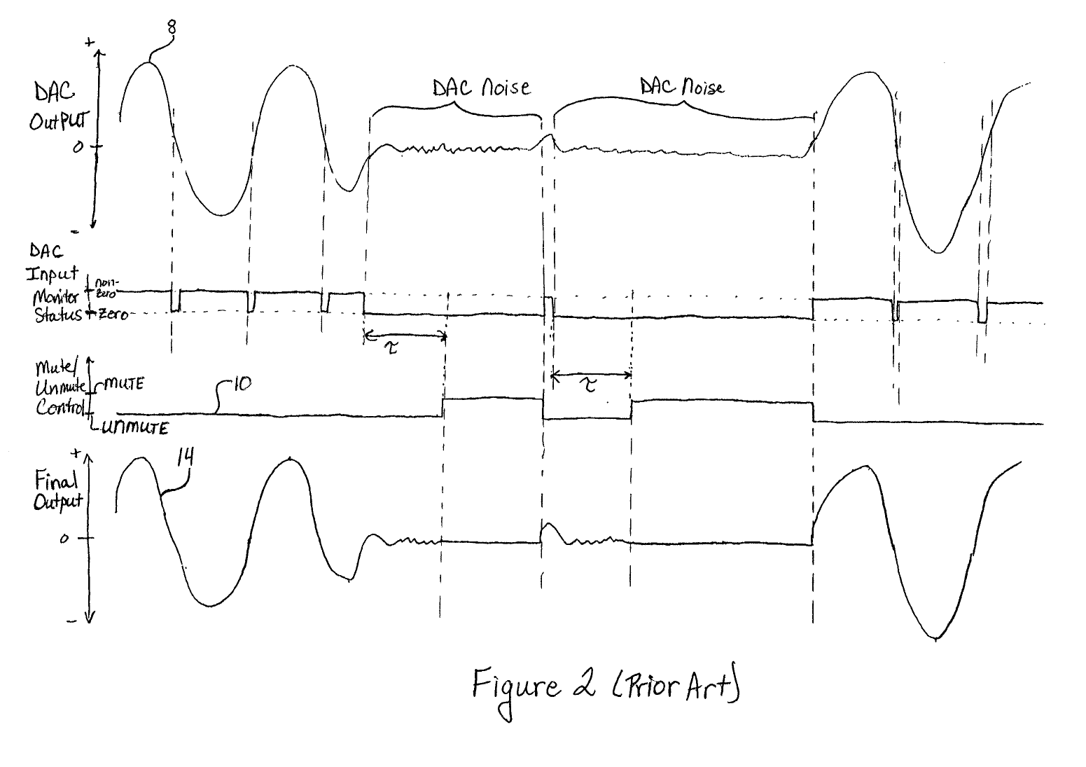

### DETAILED DESCRIPTION OF THE PREFERRED EMBODIMENTS

According to an embodiment of the present invention, a digital filter bank is disclosed to accept a preliminary digital output from an ADC and divide it into a plurality of frequency subband signals. A plurality of mute/un mute circuits are also disclosed, each of which accepts one of the plurality of frequency subband signals and compares it to a noise threshold range. This noise threshold range is defined as a range of output level within which a frequency subband signal would typically fall within if there was no signal present. However, if any significant signal energy were present in a particular frequency subband, then the level of the subband signal would be outside of this range often. For example, assume an ADC produces a bipolar digital output varying from levels of −1.0 to +1.0, and in the presence of no signal the output would be approximately zero, except for noise produced within the ADC circuitry itself. After subband filtering, assume one subband signal output is also approximately zero in the presence of any signal energy, with noise that causes this output to vary within a range of −0.0001 to +0.0001. In this case, we may set a noise threshold range from −0.0002 to +0.0002 for detection of signal. If the subband signal output goes outside this range (i.e., above +0.0002 or below −0.0002) then we are confident that signal energy is present.

If the subband signal output stays within this range (i.e., above −0.0002 and below +0.0002) for a predetermined length of time, then we are confident no significant signal energy is present. The predetermined length of time is necessary to ensure that an error in signal detection does not occur. If we do have a signal present, such as a large sine wave, there are short periods of time when the sine wave will have a value near zero, so the subband signal will also have a value falling within the noise threshold range. However, the signal causes the subband signal to soon be outside the noise threshold range again, so waiting the predetermined length of time and making sure the subband signal falls within the noise threshold range for the entire length of time ensures that no significant signal is present. In response to the comparison circuit and timing circuitry measuring the predetermined length of time, each mute/unmute circuit determines whether to output the subband signal or a reduced value signal. The mute/unmute circuit also generates an unmute signal immediately when the subband signal is outside of the noise threshold range, in order to ensure that significant values of the ADC output signal are passed as soon as they appear. The plurality of muted or unmuted frequency subband signals are then recombined in a mixing or summation operation to generate a final digital output.

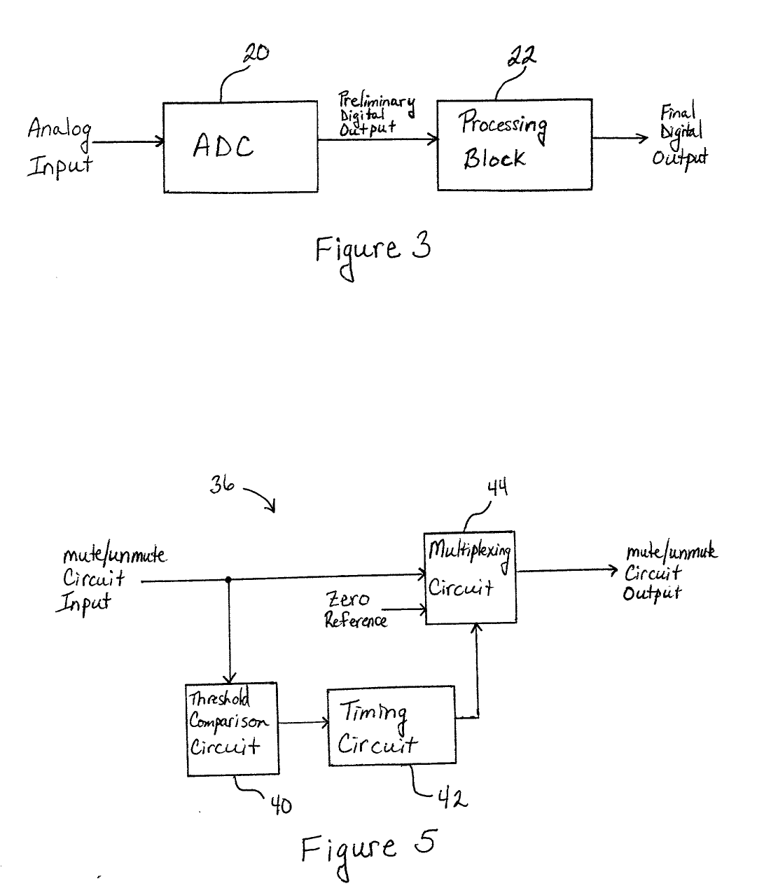

In reference to FIG. 3, the techniques described in association with embodiments of the present invention may be applied to an existing ADC 20 as a digital processing block 22 that takes the original output signal of the ADC (“preliminary digital output”), processes it, and then provides a new output signal (“final digital output”) to the user. The techniques and circuitry described herein may also be integrated into a new ADC design, particularly one that already uses significant digital filtering, to perform the processing operation combined with other filtering or processing that is already necessary. The present invention is particularly useful in ADC designs where sufficient digital filtering hardware is already available. In ADC designs that use delta-sigma modulators, most have significant digital filtering present. Some implement the filtering in a programmable engine having a capacity which depends on its design and clock rate. Typically, for efficiency of space and power, an engine is not designed with much excess capacity. However, the programmable engine may be designed with excess capacity, or occasionally a programmable engine has sufficient excess capacity to handle the additional programming necessary to implement the additional filtering.

In conventional ADC designs, the noise generated within the ADC is primarily white noise evenly spread throughout the signal bandwidth of interest. This means that there is approximately equal white noise energy per unit bandwidth. The total noise in an ADC output, which is used to calculate its signal to noise ratio, is the integration of this noise energy per unit bandwidth across the entire signal bandwidth. For example, without further post ADC processing, the overall noise voltage of an ADC with a fullscale input of 1 Vᵣₘₛ, a signal bandwidth from 20 Hz to 20 kHz and a white noise floor density of 100 nV/rt Hz, is described by the equation:

Noise (in Volts,rms)=

$$\text{Noise (in Volts,rms)} = \sqrt{{\int }_{fstart = 20 Hz}^{fstop = 20 kHz} {( 100 n Vrms / \sqrt{Hz} )}^{2} ⅆ f} = 14.135 µVrms$$

The signal to noise ratio (“SNR”) of the same ADC is described by the equation:

$$SNR = 20 \cdot log ( \frac{1 Vrms}{14.135 µVrms} ) = 96.99 dB$$

The 1 Vᵣₘₛ in the equation is an exemplary signal level for this example and will change if a different signal level is used in practice. (Those skilled in the art know that the term V/rt Hertz means “volts per root Hz” or volts per square root of Hz, and is a unit of noise spectral density. The noise in a wideband spectrum is the square root of the sum of the volts squared noise components.)

The present invention takes advantage of the possibility that any signal energy present in the preliminary output may be localized to only one or a few of the frequency subbands, not spread throughout all of them. In reference to an embodiment of the present invention illustrated in FIG. 4, the output signal of an ADC 20 is passed through a digital filter bank 24, such as a perfect reconstruction filter bank. The filter bank 24 includes a plurality of parallel filters that divide the preliminary digital output signal into multiple frequency subband signals, similar to the way a graphic equalizer in a stereo operates. For example, in an embodiment where the signal bands are divided into 256 equal bands each having frequency bandwidths of approximately 78 Hz, a low pass filter 26 is used to isolate the signal components having a frequency below 78 Hz, a high pass filter 28 is used to isolate the signal components having a frequency above 19922 Hz, and bandpass filters 30, 32 and 34 are used to isolate the various frequency subband ranges in between.

As will be clear to those of ordinary skill in the art, there are various equivalent methods known in the art for generating frequency subbands. Another common method is to use a plurality of cascaded filters. By using cascaded filters, the first stage could divide the input spectrum into two parts, such as 20 Hz-10 kHz and 10 kHz-20 kHz. The second stage could then take each of these frequency subbands and further divide them into two parts, such as 20 Hz-5 kHz, 5 kHz-10 kHz, 10 kHz-15 kHz and 15 kHz-20 kHz. This cascading method of dividing the frequency subbands can continue until the desired frequency subband ranges are generated. Additionally, it will be clear to those of ordinary skill in the art that the frequency subbands used for the present invention are not necessarily distinct subbands and may overlap with other subbands. For the present invention, the method of generating frequency subbands is not as important as having the frequency subbands themselves.

The individual outputs from the filter bank 24, each representing a different frequency subband, are then processed separately by mute/unmute processing circuits 36 which each perform a squelch, or mute, operation on its respective subband. The output from each mute/unmute processing circuit 36 is summed at a summing node 38 to form a final digital output signal for the system. The summing node 38 may be a digital adder or other circuitry known in the art for summing multiple input signals to produce a single output signal.

In reference to the operation of the mute/unmute processing circuits 36, the respective frequency subband signals are each evaluated to determine whether a significant level of signal exists. If no signal is detected in a particular subband, that subband is muted. Thus, if there is no signal component at all in any subband, all subbands will be muted. If there are only signal components in, for example, three subbands, all other subbands will be muted and only the noise from the three subbands will remain when the individual subbands are recombined. As will be clear to one of ordinary skill in the art, where there is significant signal energy present in all subbands, there is no improvement to the signal to noise ratio of the system using this method of noise reduction over a squelch operation performed on the total output. However, it is not expected that the input signal will have signal energy in every subband all the time.

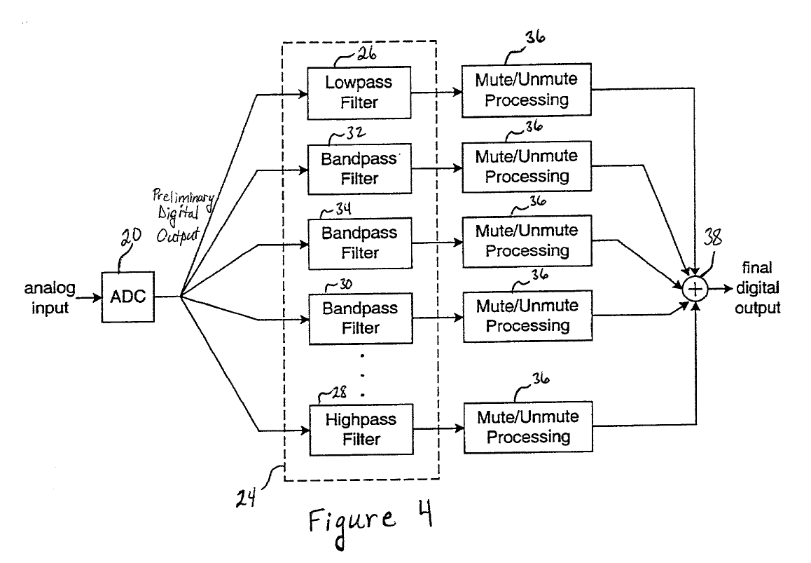

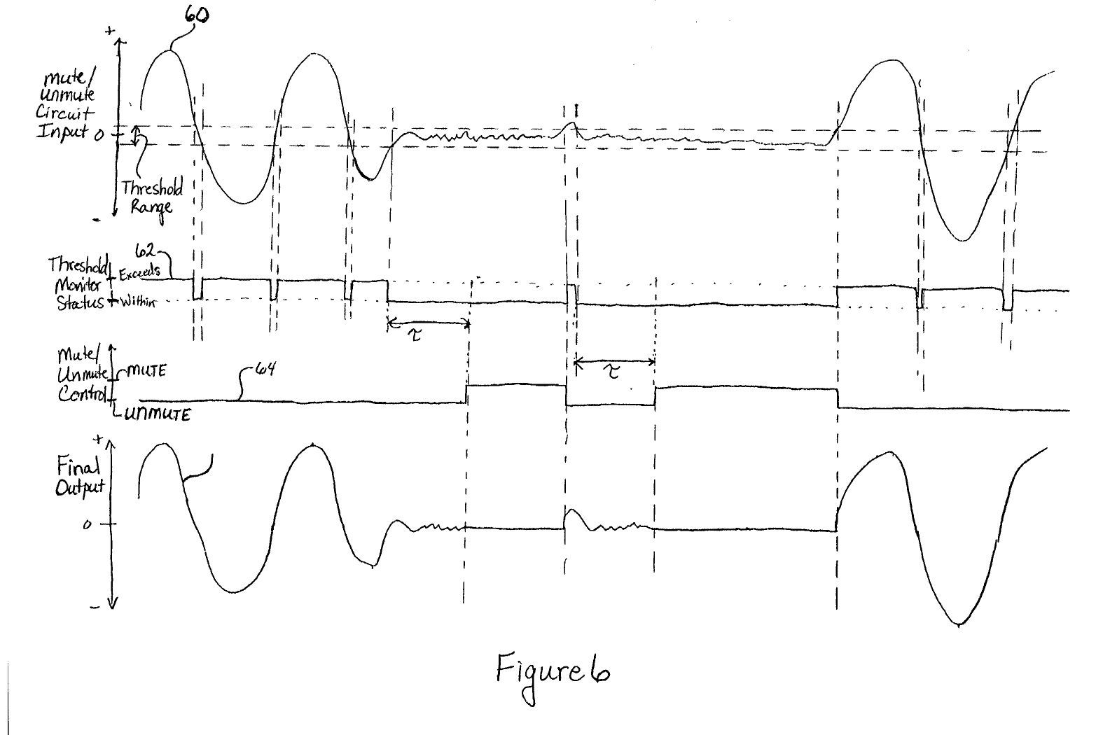

FIG. 5 is a block diagram of a mute/umnute processing circuit 36, such as that shown in FIG. 4, according to an embodiment of the present invention. The circuit includes a threshold comparison circuit 40, a timing circuit 42, and a digital multiplexing circuit 44. The mute/un rute processing circuit 36 receives an input signal which it compares to a threshold designed into the threshold comparison circuit 40. As shown in the timing diagram of FIG. 6, the threshold comparison circuit 40 monitors the mute/unmute circuit input signal 60, which represents only one frequency subband of the ADC preliminary output, and indicates whether the mute/unmute circuit input signal 60 is outside of the threshold range or is within the threshold range. This indication is represented by the threshold monitor status signal 62 shown in FIG. 6.

Each time the timing circuit 42 receives an indication from the threshold comparison circuit 40 that the input signal for a particular frequency subband is within the noise threshold range, the timing circuit 42 begins a timing sequence. If the input signal has not been outside of the threshold range for a time τ, the timing circuit 42 sends an appropriate control signal 64 to the multiplexing circuit 44 to indicate that the input signal should be muted. For this embodiment, the input signal is muted by passing a “zero value” signal instead of the noise signal. The zero value is taken from the Zero Reference input to the multiplexing circuit 44.

However, the signal passed may alternatively be an attenuated or reduced value or scaled version of the noise signal, a zero value signal being an extremely attenuated signal. The attenuated signal may be generated by multiplying the input signal by any gain factor less than 1.0. The gain factor may be a fixed gain factor, or may alternatively be adjustable in relation to the signal values in other frequency subbands. Similarly, the frequency subband signals which are passed when the input signal is outside of the noise threshold range may be passed directly, or may alternatively be passed as a signal multiplied by a gain factor, including a gain factor greater or less than 1.0.

Whenever the timing circuit 42 receives an indication that the mute/unmute circuit input signal 60 is again exceeding or outside of the threshold range, it immediately sends an appropriate control signal 64 to the multiplexing circuit 44 indicating that the multiplexing circuit 44 should simultaneously pass the mute/unmute circuit input signal 60.

As will be clear to one of ordinary skill in the art, some data converters produce a bipolar digital output, and some produce a unipolar digital output. The examples provided herein illustrate a bipolar digital output, and therefore require both a positive and a negative input signal threshold, or a threshold range. Alternatively, the absolute value of the input signal could be calculated and compared to a single threshold. For a unipolar digital output, the input signal could merely be compared to a single threshold. Furthermore, the threshold range need not be symmetrical about zero. For example, the positive and negative thresholds acting as boundaries for the threshold range could be set at +0.001 and −0.0009. Each application will have its own characteristics and requirements.

An added benefit of this invention is that, due to the signal bandwidth being divided into smaller subbands, the noise energy that falls into each subband is less than the whole integrated noise energy over the entire signal band. This allows a system designer to set the noise threshold for muting the signal in each subband much lower than previously possible in a system which mutes the noise for the entire preliminary ADC output in one step. For example, in an ADC with a noise floor of 100 nV/rt Hz and a 1 Vᵣₘₛ maximum signal level, if the signal is divided into 256 equal subbands of 78 Hz each, each subband includes a noise energy of approximately 883 nVᵣₘₛ, or 1/16th that of the entire band. Therefore, the threshold for squelching each subband could be set at a low level, such as 4-8 μVᵣₘₛ, far below the 14.125 μVᵣₘₛ noise level of the full signal band. If the input signal includes energy in only one subband, then all subbands but one would be muted and the final output noise level would be only 883 nVᵣₘₛ. This could potentially yield a signal to noise ratio of 121.08 dB, a 24 dB improvement over the case where no post ADC processing is done.

The dynamic range of the ADC system of the present invention is limited by the lowest input signal level which can be distinguished from the noise signal of a single subband. For the example provided above, that range would stop at the threshold level of the subband. For an estimated threshold level of 6 μVᵣₘₛ, this results in a dynamic range of approximately 104 dB, a 7 dB improvement over the case where no post ADC processing is done (in which case, the dynamic range would be limited to the same level as the SNR, or 96.99 dB).

It should be noted that to practice the present invention, it is not necessary to have any particular number of frequency subbands, or even to have frequency subbands of equal widths. Any number of frequency subbands of equal or varying widths may be used depending on the resolution and quality of output desired and the circuit space available. Furthermore, in some applications, the signals in one or more frequency subbands, or near one or more of the bandwidth boundaries may be unneeded. In such cases, those unnecessary frequency subbands may be filtered out. It should also be noted, however, that if the subband width is changed, the threshold level will likely also need to be changed.

The principles of the present invention may also be accomplished by varying the order of circuitry or steps, or through various combinations of circuitry components. For example, it is possible to include the filtering and mute/unmute processing circuitry in the digital decimation filtering circuits of an ADC having a delta-sigma modulator to process the data at a different rate or to minimize redundant circuitry. Another option is to place the filter bank and mute/unmute processing circuits immediately after the delta-sigma modulator and before the reconstruction of the signal by summing node 38 and the decimation filtering. Some of the decimation filtering may even be split to perform a portion of the decimation filtering before the filter bank and mute/unmute processing circuitry and some after it, but before reconstruction. In many of these options, however, the result is suboptimal because the required hardware increases.

Another possible embodiment of the present invention is to apply the present invention to an ADC that converts a bandpass signal spectrum rather than a lowpass spectrum as shown above. This application of the invention is useful for some communications applications where the signal of interest is band-centered around a high frequency carrier wave (RF or IF), and the conversion of the signal may or may not be modulated down to a baseband, or near DC, signal.

Although the present invention has been shown and described with reference to particular preferred embodiments, various additions, deletions and modifications that are obvious to a person skilled in the art to which the invention pertains, even if not shown or specifically described herein, are deemed to lie within the scope of the invention as encompassed by the following claims.

What is claimed is:

1. A noise reduction circuit for use with an analog-to-digital converter (ADC) configured to receive an analog input signal and convert it to a preliminary digital output signal having a bandwidth, the noise reduction circuit comprising:
a plurality of signal filters each coupled to an output of the ADC, the plurality of signal filters, respectively, each being configured to receive the preliminary digital output signal and pass a corresponding frequency subband portion of the bandwidth;
a plurality of mute/unmute processing circuits each coupled to an output of a corresponding signal filter, and configured to output an attenuated value if the corresponding frequency subband portion is within a predetermined threshold range continually without going outside the range for a period of time exceeding a predetermined time, and to output the corresponding frequency subband portion of the bandwidth if the corresponding frequency subband portion is outside of the predetermined threshold range; and
a summing node coupled to an output of each of the plurality of mute/unmute processing circuits and configured to sum signals from the outputs to generate a final digital output signal.

2. The noise reduction circuit of claim 1, wherein the plurality of signal filters comprises a plurality of bandpass filters.

3. The noise reduction circuit of claim 2, wherein the plurality of signal filters further comprises a low pass filter and a high pass filter.

4. The noise reduction circuit of claim 1, wherein each of the plurality of mute/unmute processing circuits comprises:
a multiplexing circuit having a first input coupled to receive the output of a corresponding signal filter and a second input coupled to receive the attenuated signal, the multiplexing circuit being configured to pass either the corresponding frequency subband portion or an attenuated signal in response to a timing circuit signal; and
a threshold comparison circuit coupled to receive the output of the corresponding signal filter, the threshold comparison circuit being configured to generate a threshold comparison signal in response to an evaluation of the corresponding frequency subband portion; and
a timing circuit coupled between an output of the threshold comparison circuit and a control input of the multiplexing circuit, the timing circuit being configured to receive the threshold comparison signal and to generate a timing circuit output signal on the control input to control whether the multiplexing circuit passes the frequency subband portion or the attenuated signal.

5. The noise reduction circuit of claim 1, wherein the summing node includes a digital adder.

6. The noise reduction circuit of claim 1, wherein the attenuated signal is a zero value signal.

7. The noise reduction circuit of claim 1, wherein the attenuated signal is the subband frequency signal scaled by a gain factor less than 1.0.

8. An analog-to-digital converter circuit (ADC) configured to convert analog signals into corresponding digital signals in the form of a preliminary output signal having a bandwidth, the ADC comprising:
a filter bank comprising at least one input and a plurality of filter outputs, the filter bank configured to receive the preliminary output signal, and produce a plurality of subband output signals representing a corresponding portions of the bandwidth, respectively;
a plurality of mute/un mute circuits each having an input coupled to one of the plurality of filter outputs, respectively, and an output conducting a corresponding subband output signal, each mute/unmute circuit being configured to pass an attenuated signal to its output when the corresponding subband output signal's value has been within a threshold range for at least a predetermined length of time, and pass the corresponding subband output signal to its output when either the subband output signal's value has been within the threshold range for less than the predetermined length of time or has been outside the threshold range; and
a summing node coupled to the output of each of the plurality of mute/unmute circuits and configured to sum the subband output signals from the mute/unmute circuits together to generate a final digital output signal.

9. The ADC of claim 8, wherein the filter bank comprises a plurality of bandpass filters.

10. The ADC of claim 9, wherein the filter bank further comprises a low pass filter and a high pass filter.

11. The ADC of claim 8, wherein each of the plurality of mute/unmute circuits comprises:
a multiplexing circuit having a first input coupled to receive a corresponding filter bank output and a second input coupled to receive the attenuated signal, the multiplexing circuit being configured to pass either the subband output signal or the attenuated signal in response to a timing circuit signal;
a threshold comparison circuit coupled to receive the corresponding subband output signal and configured to determine whether the corresponding subband output signal is within or is outside of the threshold range and to generate a threshold comparison signal in response to the determination; and
a timing circuit coupled between an output of the threshold comparison circuit and a control input of the multiplexing circuit, the timing circuit being configured to receive the threshold comparison signal and to responsively generate a control signal on the control input to control whether the multiplexing circuit passes the corresponding subband output signal or the attenuated value.

12. The noise reduction circuit of claim 8, wherein the attenuated value signal is a zero value signal.

13. The noise reduction circuit of claim 8, wherein the attenuated value signal is the subband frequency signal scaled by a gain factor less than 1.0.

14. A method for reducing noise in an output signal of an analog-to-digital converter (ADC), the method comprising:
dividing the output signal into frequency subbands;
processing a frequency subband signal in each of the subbands by passing the frequency subband signal in each of the subbands to a corresponding input of a summing node if the frequency subband signal is outside of a threshold range and passing an attenuated value signal to the summing node if the signal is within the threshold range; and
generating a final output signal by summing the processed frequency subband signals at the summing node.

15. The method of claim 14, wherein processing each frequency subband signal comprises:
comparing the frequency subband signal to the threshold range;
passing the attenuated value signal after the frequency subband signal has remained within the threshold range for at least a predetermined time interval;
passing the frequency subband signal if it has not remained in the threshold range at least during the predetermined time interval; and
immediately passing the frequency subband signal if the frequency subband signal is outside of the threshold range.

16. The method of claim 14, wherein dividing the output signal into frequency subband signals comprises filtering the output signal through a plurality of bandpass filters arranged in parallel.

17. The method of claim 16, wherein dividing the output signal into frequency subband signals further comprises filtering the output signal through a high pass filter and filtering the output signal through a low pass filter.

18. The method of claim 14, wherein dividing the output signal into frequency subband signals comprises filtering the output signal through a plurality of cascaded filters.

19. The method of claim 14, further comprising setting the threshold range to be less than an overall noise range for the output signal of the ADC.

20. The method of claim 14, wherein passing the attenuated value signal comprises passing the subband frequency signal scaled by a gain factor less than 1.0.

21. The method of claim 14, wherein passing the attenuated value signal comprises passing a zero value signal.

22. A method of improving the signal-to-noise ratio of an analog-to-digital converter output signal, the method comprising:
(a) dividing the output signal into frequency subband signals, zero or more of the frequency subbands including a signal with a value outside of a threshold range and each of the frequency subbands including noise with a value within the threshold range;
(b) providing reduced value signals representative of the frequency subband signals which do not include a signal with a value outside of the threshold range and passing the reduced value signals;
(c) passing all of the frequency subband signals which include a signal with a value outside of the threshold range; and
(d) summing each of the frequency subband signals produced by steps (b) and (c) to generate a final output signal.

23. The method of claim 22, wherein attenuating the frequency subbands comprises attenuating the frequency subband after the frequency subband signal has remained within the threshold range during a predetermined time interval.

24. The method of claim 22, wherein step (b) includes multiplying the frequency subband signal by a gain factor less than 1.0.

25. The method of claim 22, wherein step (b) includes producing a zero value of the reduced value signal.
